(19) United States
(12) Patent Application Publication
(10) Pub. No.: US 2008/0128685 A1
(43) Pub. Date: Jun. 5, 2008

(54) ORGANIC SEMICONDUCTOR DEVICE, MANUFACTURING METHOD OF SAME, ORGANIC TRANSISTOR ARRAY, AND DISPLAY

(76) Inventors: Hiroyuki HONDA, Tokyo (JP); Masanao MATSUOKA, Tokyo (JP); Mitsutaka NAGAE, Tokyo (JP); Hironori KOBAYASHI, Tokyo (JP)

Correspondence Address: LADAS & PARRY LLP, 224 SOUTH MICHIGAN AVENUE, SUITE 1600, CHICAGO, IL, 60604, US

(21) Appl. No.: 11/855,295

(22) Filed: Sep. 14, 2007

(30) Foreign Application Priority Data
Sep. 26, 2006 (JP) 2006-260765

(51) Int. Cl. H01L 51/05; H01L 51/40

(52) U.S. Cl. 257/40; 438/99; 257/E51.006

(57) ABSTRACT

A major object of the present invention is to provide an organic semiconductor device which is provided with an organic semiconductor transistor having good transistor performance and is producible with high productivity. To achieve the object, the present invention provides an organic semiconductor device comprising: a substrate, a source electrode and a drain electrode which are formed on the substrate; an insulation partitioned part which is formed on the source electrode and the drain electrode, made of an insulation material, formed such that an opening part of the insulation partitioned part is disposed above a channel region formed by the source electrode and the drain electrode and has a function as an interlayer-insulation layer; an organic semiconductor layer which is formed in the opening part of the insulation partitioned part and on the source electrode and the drain electrode, and made of an organic semiconductor material; a gate insulation layer which is formed on the organic semiconductor layer and made of an insulation resin material; and a gate electrode formed on the gate insulation layer, wherein; the insulation partitioned part has a height ranging from 0.1 μm to 1.5 μm.

### BACKGROUND OF THE INVENTION

1. Field of the Invention

The present invention relates to an organic semiconductor device using an organic semiconductor transistor, a manufacturing method of the organic semiconductor device, an organic transistor array and a display.

2. Description of the Related Art

A semiconductor transistor typified by TFT shows the current trend towards spreading of its applications along with the development of display devices. Such a semiconductor transistor functions as a switching element when the electrodes are connected through a semiconductor material.

As the semiconductor material used for the semiconductor transistor, inorganic semiconductor materials such as silicon (Si), gallium arsenic (GaAs) and indium gallium arsenic (InGaAs) are used. Semiconductor transistors using such an inorganic semiconductor are also used for display TFT array substrates of liquid crystal display devices which have been widely spread in recent years.

On the other hand, organic semiconductor materials made of organic compounds are known as the semiconductor material. Organic semiconductor materials have an advantage in that: they are allowed to be increased in area at a lower cost than those using the inorganic semiconductor materials, and they can be formed on a flexible plastic substrate and are also stable against mechanical impact. Therefore, active studies are being made as to technologies regarding the organic semiconductor materials, which is assumed to be applied display devices such as flexible displays typified by electronic papers in the next generation.

When producing an organic semiconductor transistor using an organic semiconductor material like this, it is usually necessary to form the organic semiconductor layer pattern-wise. The photoresist method has been mainly used to form an organic semiconductor layer pattern-wise so far (for example, Japanese Patent Application Laid-Open No. 2006-58497). However, this photoresist method has the problem that it is inferior in productivity because its process is complicated though it is superior in the point that a layer made of an organic semiconductor material can be patterned into a desired pattern with high accuracy.

To deal with this problem, a method is disclosed in Japanese Patent Application Laid-Open No. 2006-189780, in which a partitioned part is formed and an organic semiconductor layer is formed in the opening part of the partitioned part to thereby form a patterned organic semiconductor layer. Because such a method makes it possible form to an organic semiconductor layer by an ink jet method, this method has the advantage that a finely patterned organic semiconductor layer can be formed with high productivity.

### SUMMARY OF THE INVENTION

The inventors of the present invention have made earnest studies and found that the method in which an organic semiconductor layer is produced using the partitioned part has the problem that the organic semiconductor layer formed in the opening part is uneven, while this method has the advantage that it enables the formation of an organic semiconductor device with high productivity by using such as an ink jet method. Specifically, the inventors have found that in order to form an organic semiconductor layer in the opening part of the partitioned part, it is general to use a method in which a solution containing an organic semiconductor material is injected into the opening part by using an additive method such as an ink jet method, which however poses a new problem that the organic semiconductor material is localized on the wall surface of the opening part in the course of drying the solution and it is therefore difficult to form a uniformorganic semiconductor layer in the channel region. Such a formation of an uneven organic semiconductor layer gives rise to a serious problem concerning the performance of a transistor using the organic semiconductor material. The production method of an organic semiconductor device using the partitioned part has a difficulty in obtaining industrial practicability unless the aforementioned problem is not solved.

The present invention has been made in view of these problems, and it is a main object of the present invention to provide an organic semiconductor device which is provided with an organic semiconductor transistor having good transistor performance and is producible with high productivity.

To solve the problems, the present invention provides a following embodiment. An organic semiconductor device comprising: a substrate; a source electrode and a drain electrode which are formed on the substrate; an insulation partitioned part which is formed on the source electrode and the drain electrode, made of an insulation material, formed such that an opening part of the insulation partitioned part is disposed above a channel region formed by the source electrode and the drain electrode and has a function as an interlayer-insulation layer; an organic semiconductor layer which is formed in the opening part of the insulation partitioned part and on the source electrode and the drain electrode, and made of an organic semiconductor material; a gate insulation layer which is formed on the organic semiconductor layer and made of an insulation resin material; and a gate electrode formed on the gate insulation layer, wherein; the insulation partitioned part has a height ranging from 0.1 μm to 1.5 μm.

According to the present invention, the organic semiconductor layer is formed in the opening part of the insulation partitioned part. Therefore, for example, in the process of forming the organic semiconductor device of the present invention, the organic semiconductor layer can be selectively formed in the opening part of the insulation partitioned part by using an ink jet method having high productivity.

Further, in the present invention, the height of the insulation partitioned part is in the range from 0.1 μm to 1.5 μm. Therefore, even in the case of forming an organic semiconductor layer in the opening part by using an ink jet method having high productivity, the thickness of the organic semiconductor layer to be formed in the opening part can be made uniform, so that an organic semiconductor transistor superior in transistor performance can be manufactured.

In light of the above, the present invention can provide a manufacturing method of an organic semiconductor device which is provided with an organic semiconductor transistor having good transistor performance and is producible with high productivity.

To solve the above-mentioned problems, the present invention further provides another embodiment as follows. An organic semiconductor device comprising: a substrate; a gate electrode formed on the substrate; an insulation partitioned part which is formed on the gate electrode, made of an insulation material, provided with an opening part and has a function as an interlayer-insulation layer, a gate insulation layer which is formed in the opening part of the insulation partitioned part and on the gate electrode, and made of an insulation resin material; an organic semiconductor layer which is formed in the opening part of the insulation partitioned part and on the gate insulation layer, and made of an organic semiconductor material; and a source electrode and a drain electrode which are formed on the organic semiconductor layer, wherein; the insulation partitioned part has a height ranging from 0.1 μm to 1.5 μm.

According to this embodiment, since the gate insulation layer is formed in the opening part of the insulation partitioned part, it is possible to selectively form the gate insulation layer in the insulation partitioned part by using an ink jet method having high productivity in the step of manufacturing an organic semiconductor device in this embodiment.

Further, since in this embodiment, the height of the insulation partitioned part is in the range from 0.1 μm to 1.5 μm, the gate insulation layer is formed in a uniform thickness in the opening part even in the case of forming the gate insulation layer in the opening part by using an ink jet method having high productivity, and it is therefore possible to manufacture an organic semiconductor transistor having excellent transistor performance.

Therefore, this embodiment can provide a manufacturing method of an organic semiconductor device which is provided with an organic semiconductor transistor having good transistor performance and is producible with high productivity.

In the present invention, the insulation partitioned part preferably has liquid repellency. This is because it has an advantage that, for example, ink can be introduced into the inside of the insulation partitioned part due to the liquid repellent effect in the case of forming the organic semiconductor layer or the gate insulation layer by an ink jet method and the case where the ink would be dripped on a position deviated a little from the opening part of the insulation partitioned part, thereby enabling a reduction in the defects caused by the use of an ink jet method.

The present invention also provides manufacturing method of an organic semiconductor device, wherein the method comprises: a source/drain electrode formation step of using a substrate to form a source electrode and a drain electrode on the substrate; an insulation partitioned part formation step of forming an insulation partitioned part made of an insulation material on the source electrode and the drain electrode formed in the source/drain electrode formation step such that an opening part of the insulation partitioned part is disposed above a channel region formed by the source electrode and the drain electrode and a height of the insulation partitioned part is in the range from 0.1 μm to 1.5 μm; an organic semiconductor layer formation step of forming an organic semiconductor layer made of an organic semiconductor material, in the opening part of the insulation partitioned part formed in the insulation partitioned part formation step and on the source electrode and the drain electrode; a gate insulation layer formation step of forming a gate insulation layer made of an insulation resin material ton the organic semiconductor layer formed in the organic semiconductor layer formation step; and a gate electrode formation step of forming a gate electrode on the gate insulation layer formed in the gate insulation layer formation step.

According to the present invention, the height of the insulation partitioned part produced in the insulation partitioned part formation step is in the range from 0.1 μm to 1.5 μm, the organic semiconductor layer can be formed in a uniform thickness in the opening part in the organic semiconductor layer formation step.

It is therefore possible to manufacture an organic semiconductor device provided with an organic semiconductor transistor having excellent transistor performance with high productivity.

The present invention further provides another embodiment as follows. A manufacturing method of an organic semiconductor device, wherein the method comprises: a gate electrode formation step of using a substrate to form a gate electrode on the substrate; an insulation partitioned part formation step of forming an insulation partitioned part on the gate electrode formed in the gate electrode formation step such that a height of the insulation partitioned part is in the range from 0.1 μm to 1.5 μm and an opening part of the insulation partitioned part is disposed above the gate electrode; a gate insulation layer formation step of forming a gate insulation layer made of an insulation resin material, in the opening part of the insulation partitioned part formed in the insulation partitioned part formation step and on the gate electrode; an organic semiconductor layer formation step of forming an organic semiconductor layer made of an organic semiconductor material on the gate insulation layer formed in the gate insulation layer formation step; and a source/drain electrode formation step of forming a source electrode and a drain electrode on the organic semiconductor layer formed in the organic semiconductor layer formation step.

Further, since in this embodiment, the height of the insulation partitioned part formed in the insulation partitioned part formation step is in the range from 0.1 μm to 1.5 μm, the gate insulation layer is formed uniformly in the opening part in the gate insulation layer formation step.

It is therefore possible to manufacture an organic semiconductor device provided with an organic semiconductor transistor having excellent transistor performance with high productivity.

Moreover, the present invention provides an organic transistor array using an organic semiconductor device according to an embodiment of the present invention, wherein plural organic semiconductor transistors are formed on the substrate. According to the present invention, an organic transistor array superior in on-off ratio can be obtained since the organic semiconductor device according to an embodiment of the present invention is used.

The present invention still further provides a display using the organic transistor array according to the present invention. According to the present invention, a display superior in display performance can be obtained since the organic transistor array according to the present invention is used.

The present invention produces such an effect that an organic semiconductor device, which is provided with an organic semiconductor transistor having good transistor performance and can be produced with high productivity, can be provided.

### BRIEF DESCRIPTION OF THE DRAWINGS

FIG. 1 is a schematic view showing an example of an organic semiconductor device in a first embodiment according to the present invention.

FIGS. 2A and 2B are each a schematic view for describing the advantage of an organic semiconductor device in a first embodiment according to the present invention.

FIG. 3 is a schematic view showing another example of an organic semiconductor device in a first embodiment according to the present invention.

FIG. 4 is a schematic view showing an example of an organic semiconductor device in a second embodiment according to the present invention.

FIGS. 5A and 5B are each a schematic view for describing the advantage of an organic semiconductor device in a second embodiment according to the present invention.

FIGS. 6A and 6B are each a schematic view showing one step of a manufacturing method of an organic semiconductor device in a first embodiment according the present invention.

FIGS. 7A and 7B are each a schematic view for describing a step of forming source/drain electrodes in a method of producing an organic semiconductor device in a first embodiment according the present invention.

FIGS. 8A and 8B are each a schematic view for describing a step of forming an insulation partitioned part in a method of producing an organic semiconductor device in a first embodiment according the present invention.

FIGS. 9A and 9B are each a schematic view for describing a step of forming an organic semiconductor layer in a method of producing an organic semiconductor device in a first embodiment according the present invention.

FIGS. 10A and 10B are each a schematic view for describing a step of forming a gate insulation layer in a method of producing an organic semiconductor device in a first embodiment according the present invention.

FIGS. 11A and 11B are each a schematic view for describing a step of forming a gate electrode in a method of producing an organic semiconductor device in a first embodiment according the present invention.

FIGS. 12A and 11B are each a schematic view for describing a step of forming a gate electrode in a method of producing an organic semiconductor device in a second embodiment according the present invention.

FIGS. 13A and 13B are each a schematic view for describing a step of forming a gate electrode in a method of producing an organic semiconductor device in a second embodiment according the present invention.

FIGS. 14A and 14B are each a schematic view for describing a step of forming an insulation partitioned part in a method of producing an organic semiconductor device in a second embodiment according the present invention.

FIGS. 15A and 15B are each a schematic view for describing a step of forming a gate insulation layer in a method of producing an organic semiconductor device in a second embodiment according the present invention.

FIGS. 16A and 16B are each a schematic view for describing a step of forming an organic semiconductor layer in a method of producing an organic semiconductor device in a second embodiment according the present invention.

FIGS. 17A and 17B are each a schematic view for describing a step of forming source/drain electrodes in a method of producing an organic semiconductor device in a second embodiment according the present invention.

### DESCRIPTION OF THE PREFERRED EMBODIMENT

The present invention relates to an organic semiconductor device, a manufacturing method of the organic semiconductor device, an organic transistor array and a display. The organic semiconductor device of the present invention and the manufacturing method of the organic semiconductor device will be described.

In the present invention, the term “organic semiconductor transistor” indicates a structure involving a combination of a source electrode, a drain electrode, an organic semiconductor layer, a gate insulation layer and a gate electrode.

A. Organic Semiconductor Device

First, the organic semiconductor device of the present invention will be described. The organic semiconductor device of the present invention may be roughly classified into two embodiments typified by a first embodiment provided with an organic semiconductor transistor having a top gate type structure and a second embodiment provided with an organic semiconductor transistor having a bottom gate type structure.

The organic semiconductor transistor to be used in the present invention will be described in each type separately.

A-1: Organic Semiconductor Transistor in a First Embodiment

An organic semiconductor transistor in a first embodiment of the present invention will be explained first. The organic semiconductor transistor of this embodiment comprises an organic semiconductor transistor having a top gate type structure.

An organic semiconductor device of this embodiment comprises: a substrate; a source electrode and a drain electrode which are formed on the substrate; an insulation partitioned part which is formed on the source electrode and the drain electrode, made of an insulation material, formed such that an opening part of the insulation partitioned part is disposed above a channel region formed by the source electrode and the drain electrode and has a function as an interlayer-insulation layer; an organic semiconductor layer which is formed in the opening part of the insulation partitioned part and on the source electrode and the drain electrode, and made of an organic semiconductor material; a gate insulation layer which is formed on the organic semiconductor layer and made of an insulation resin material; and a gate electrode formed on the gate insulation layer, wherein; the insulation partitioned part has a height ranging from 0.1 μm to 1.5 μm.

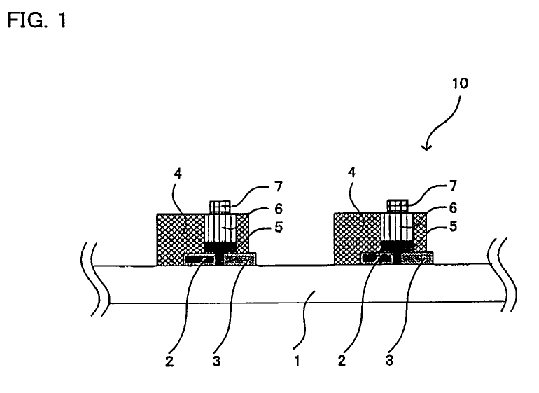

Such an organic semiconductor device in this embodiment will be described with reference to the drawing. FIG. 1 is a schematic view showing an example of the organic semiconductor device of this embodiment. As illustrate in FIG. 1, an organic semiconductor device 10 of this embodiment comprises: a substrate 1; a source electrode 2 and a drain electrode 3 which are formed on the substrate 1; an insulation partitioned part 4 which is made of an insulation material and formed such that it is provided with its opening part above a channel region formed between the source electrode 2 and the drain electrode 3 and has a function as an interlayer-insulation layer; an organic semiconductor layer 5 which is formed within the opening part of the insulation partitioned part 4 and above the source electrode 2 and drain electrode 3 and is made of an organic semiconductor material; a gate insulation layer 6 which is formed on the organic semiconductor layer 5 and made of an insulation resin material; and a gate electrode 7 formed on the gate insulation layer 6. In such an example, the organic semiconductor device 10 in this embodiment is characterized by the structure in which the insulation partitioned part 4 has a height ranging from 0.1 μm to 1.5 μm.

According to this embodiment, the organic semiconductor layer is formed in the opening part of the insulation partitioned part, and it is therefore possible to form the organic semiconductor layer and gate insulation layer selectively in the insulation partitioned part by using an ink jet method having high productivity in the process of manufacturing the organic semiconductor device in this embodiment. Also, in this embodiment, the insulation partitioned part has a height ranging from 0.1 μm to 1.5 μm and therefore, even in the case where the organic semiconductor layer would be formed in the opening part by using an ink jet method having high productivity, the organic semiconductor layer to be formed in the opening part can be formed uniformly and it is therefore possible to manufacture an organic semiconductor transistor having a high transistor performance.

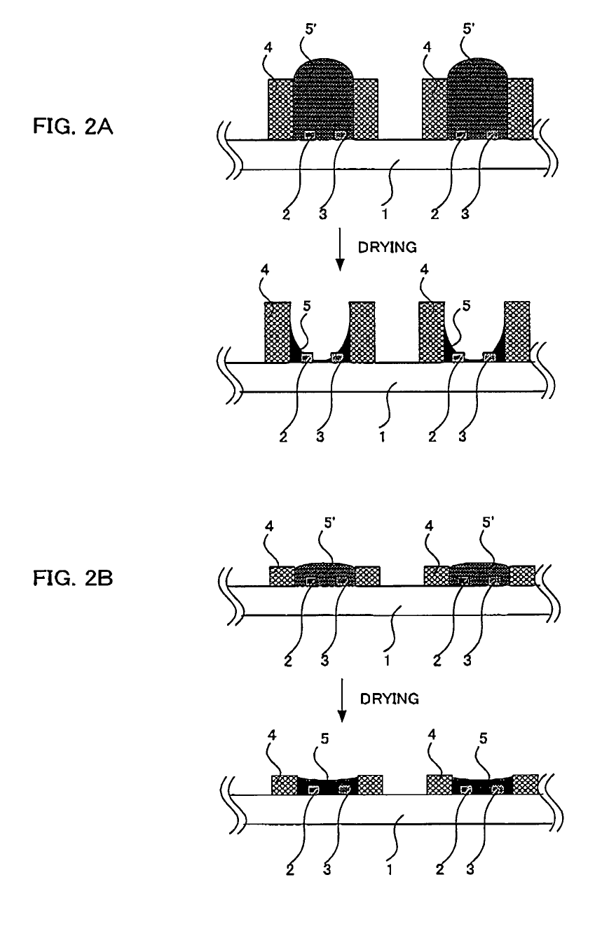

Here, the reason why the organic semiconductor layer can be uniformly formed in the opening part when the height of the insulation partitioned part is made to fall in the aforementioned range in this embodiment will be described. FIGS. 2A and 2B are each a schematic view when the organic semiconductor layer is formed in the opening part of the insulation partitioned part. FIG. 2A is an example of the case where the height of the insulation partitioned part is high like the case of conventional organic semiconductor devices, and FIG. 2B is an example of the case where the height of the insulation partitioned part is low like the case of this embodiment.

If an organic semiconductor layer formation coating solution 5′ containing an organic semiconductor material is coated to the inside of the opening part and then dried when the insulation partitioned part 4 is high as illustrated in FIG. 2A, the organic semiconductor layer 5 is eventually formed in the manner that the organic semiconductor material is formed locally on the wall surface of the opening part by the effect of a difference in drying speed. As a result, the thickness of the organic semiconductor layer 5 becomes uneven and it is difficult to form the organic semiconductor layer 5 having a necessary thickness on the channel region formed by the source electrode 2 and the drain electrode 3. The case where the height of the insulation partitioned part is high in turn causes an increase in the thickness of the organic semiconductor layer 5 formed in the vicinity of the wall surface of the opening part and leak current arises from the vicinity of the wall surface, giving rise to the problem that the transistor performance is damaged.

However, if the height of the insulation partitioned part 4 is reduced as illustrated in FIG. 2B, it is possible to prevent such a phenomenon that the organic semiconductor material is formed locally on the wall surface of the insulation partitioned part 4, resulting in that a uniform organic semiconductor layer 5 can be formed in a necessary thickness above the channel region.

From this fact, this embodiment ensures to provide a manufacturing method of an organic semiconductor device which has an organic semiconductor transistor having good transistor performance and can be produced with high productivity.

The organic semiconductor device in this embodiment is provided with at least the substrate, source electrode, drain electrode, insulation partitioned part, organic semiconductor layer, gate insulation layer and gate electrode.

Each of the structures to be used in the organic semiconductor device of this embodiment will be described.

1. Insulation Partitioned Part

First, the insulation partitioned part to be used in this embodiment will be described. The insulation partitioned part to be used in this embodiment is made of an insulating material and is formed such that, at least, its opening part is disposed above the channel region formed by the source and drain electrodes which will be described later. The height of the insulation partitioned part used in this embodiment is in the range from 0.1 μm to 1.5 μm. The insulation partitioned part to be used in this embodiment also has a function as an interlayer-insulation layer.

Hereinafter, such an insulation partitioned part will be described.

The insulation partitioned part used in this embodiment has a function as an interlayer-insulation layer. Here, the function as an interlayer-insulation layer means the function of insulating the gate electrode from a data line to be connected to the source electrode in the area other than the opening part.

The height of the insulation partitioned part used in this embodiment is in the range from 0.1 μm to 1.5 μm. The reason why the height of the insulation partitioned part is limited to this range is that if the height exceeds the range, the organic semiconductor layer to be formed in the opening part is disposed locally in the vicinity of the wall surface of the opening part and therefore, the performance of the organic semiconductor transistor to be formed is damaged. Also, if the height is below the range, there is the case where the organic semiconductor layer to be formed in the opening part becomes so thin that no desired ability can be developed. Further, if the thickness is below the range, there is the case where, when liquid repellency is imparted to the insulation partitioned part used in this embodiment, it is difficult to impart sufficient liquid repellency.

Here, the height of the insulation partitioned part to be used in this embodiment is preferably in the range from 0.1 μm to 1.5 μm, and more preferably in a range from 0.1 μm to 0.5 μm, though no particular limitation is imposed on it insofar as it is in the aforementioned range.

There is no particular limitation to the structure in which the insulation partitioned part is formed in the organic semiconductor device of this embodiment as long as it is formed such that, at least, its opening part is disposed above the channel region formed by the source and drain electrodes which will be described later. Here, the aforementioned “channel region” means only the region sandwiched between the channel parts of the source and drain electrodes which will be described later.

In this embodiment, no particular limitation is imposed on the structure in which the insulation partitioned part is formed such that its opening part is disposed above the channel region insofar as at least a part of the area above the channel region constitutes the opening part of the insulation partitioned part. Therefore, the embodiment in which the insulation partitioned part is formed in this embodiment may be: a structure in which a part of the channel region is received in the opening, part or a structure, in which all of the channel region is received in the opening part. Among these structures, the insulation partitioned part in this embodiment is preferably formed in such a structure in, which all of the channel region is received in the opening part. The reason is as follows.

Specifically, an organic semiconductor layer and a gate insulation layer which will be described later are to be formed in the opening part of the insulation partitioned part. In this case, the variations in the thickness of the organic semiconductor layer and gate insulation layer tend to increase in the vicinity of the wall surface of the opening part. Therefore, when the insulation partitioned part in the present invention is formed in such a manner that a part of the channel region is received in the opening part, there is the possibility of a transistor being deteriorated in its performance by the effect of the variation in thickness. However, when the insulation partitioned part is formed such that all of the channel region is received in the opening part, such a problem scarcely arises.

There is no particular limitation to the structure involving the formation of the insulation partitioned part in this embodiment insofar as it allows the insulation partitioned part to develop a function as an interlayer-insulation layer.

It is described below as to the case where the insulation partitioned part having such a structure is formed in this embodiment with reference to the drawings. FIG. 3 is a schematic sectional view showing another example of the organic semiconductor device of this embodiment. As illustrate in FIG. 2B, in an organic semiconductor device 10 according to this embodiment, an insulation partitioned part 4′ is preferably integrated with neighboring organic semiconductor transistors.

No particular limitation is imposed on the insulation material used for the insulation partitioned part in this embodiment insofar as it has the ability of insulating the gate electrode to a desired extent from the source and drain electrodes which will be described later in the organic semiconductor device. As the insulation material, an optional material may be properly selected and used in accordance with factors such as the height of the insulation partitioned part. Among these materials, an insulation material having a dielectric breakdown strength ranging preferably from 200V/μm to 300V/μm, and more preferably from 250 V/μm to 300 V/μm is used as the insulation material used in this embodiment.

Here, as the dielectric breakdown strength, the value found by the following method is used.

1) First, a device having a structure in which an insulation material which is a subject of evaluation is sandwiched between electrodes is prepared.

2) Next, a voltage V of 0 to 300 V is applied between the upper and lower electrodes to measure a current value I flowing between the upper and lower electrodes.

3) Based on the obtained data of current I, the resistance R (value obtained by dividing the applied voltage by the current value) of the insulation layer is plotted as a factor of the field strength E (value obtained by dividing the applied voltage V by the film thickness “d” of the insulation layer) on a graph in which the abscissa is the field strength E and the ordinate is the resistance R. From the graph produced in this manner, the value E₀ of the field strength at which the resistance R suddenly drops is defined as dielectric breakdown strength.

Moreover, the insulation material used in this embodiment has a volume specific resistance of preferably 1×10¹⁵ Ω·cm or more, and more preferably 1×10¹⁷ Ω·cm or more.

Here, as the volume specific resistance, a value obtained by measuring according to JIS K 6911 is adopted.

As the insulation material to be used in this embodiment, it is preferable to use a photosetting resin among insulation materials having the aforementioned insulation ability and volume specific resistance. The reason is that the use of the photosetting resin makes it easy to form a finely patterned insulation partitioned part because the insulation partitioned part can be formed by a photolithographic method in the process of producing an organic semiconductor device according to this embodiment.

As examples of such insulation material, acryl type resins, phenol type resins, fluorine type resins, epoxy type resins, cardo-type resins, vinyl type resins, imide type resins and novolac resins can be cited. Among them, acryl type resins, fluorine type resins, or cardo-type resins are suitably used in the present embodiment.

Also, the insulation partitioned part used in this embodiment preferably has liquid repellency. This is because it has an advantage that ink can be introduced into the inside of the insulation partitioned part due to the liquid repellent effect in the case of forming the organic semiconductor layer or the gate insulation layer by an ink jet method and the case of the ink would be dripped on a position deviated a little from the opening part of the insulation partitioned part, enabling a reduction in the defects caused by the use of an ink jet method.

Here, the term “liquid repellency” means liquid repellency from a coating solution coated to the inside of the insulation partitioned part when the organic semiconductor device of this embodiment is produced.

As to the level of the liquid repellency, it may be appropriately adjusted in accordance with factors such as the surface tension of a coating solution to be coated to the inside of the insulation partitioned part when the organic semiconductor device of this embodiment is produced. However, in this embodiment, the contact angle of the insulation partitioned part with distilled water is preferably 80° or more.

Here, the contact angle may be measured using Drop Master 700 manufactured by Kyowa Interface Science Co., Ltd.

No particular limitation is imposed on the structure in which the insulation partitioned part used in this embodiment to have liquid repellency insofar as the surface of the insulation partitioned part can develop desired liquid repellency. Examples of such a structure may include: a structure in which a material having liquid repellency is used as the insulation material, and a structure in which a resin material having no liquid-repellency is used as the insulation material and after the insulation partitioned part is formed using the resin material, the surface of the insulation partitioned part is processed by liquid repellent treatment to provide liquid repellency. An insulation partitioned part to which liquid repellency is given in either of the above structures may be preferably used in this embodiment.

Here, examples of the insulation material having liquid repellency may include fluororesins, acryl resins and cardo-type resins.

Also, as the liquid-repellent treatment, a method in which plasma using a fluorine compound as an introduction gas is irradiated may be used. Examples of the fluorine compound as the introduction gas may include CF₄, SF₆, CHF₃, C₂F₆, C₃He and No particular limitation is imposed on the method of irradiating plasma as long as it is a method of improving the liquid repellency of the insulation partitioned part and, for example, plasma may be irradiated under reduced pressure or under an atmosphere.

In the case of performing the liquid repellent treatment using irradiation of plasma, fluorine exists on the surface of the insulation partitioned part used in this embodiment and the existence of fluorine like this can be confirmed by an analysis using an X-ray photoelectron spectral analyzer (XPS: ESCALAB 220i-XL).

2. Organic Semiconductor Device

Next, the organic semiconductor device used in this embodiment will be described. The organic semiconductor layer used in this embodiment is formed in the opening part of the insulation partitioned part mentioned-above and on the source and drain electrodes which will be described later. Also, the organic semiconductor layer used in the present invention is made of an organic semiconductor material.

The organic semiconductor layer used in this embodiment will be described.

No particular limitation is imposed on the organic semiconductor material used in this embodiment insofar as it is a material capable of forming an organic semiconductor layer having desired semiconductor characteristics according to the use of the organic semiconductor device of this embodiment, and organic semiconductor materials which are usually used for organic semiconductor transistors may be used. Examples of the organic semiconductor material may include π-electron conjugate type aromatic compounds, chain type compounds, organic pigments and organic silicon compounds. Specific examples of the organic semiconductor material may include: low-molecular organic semiconductor materials such as pentacene, and high-molecular type organic semiconductor materials, for example, polypyrroles such as polypyrrol, poly(N-substituted pyrrole), poly(3-substituted pyrrole) and poly(3,4-disubstituted pyrrole), polythiophenes such as polythiophene, poly(3-substituted thiophene), poly(3,4-disubstituted thiophene) and polybenzothiophene, polyisothianaphthenes such as polyisothianaphthene, polythenylenevinylenes such as polythenylenevinylene, poly(p-phenylenevinylenes) such as poly(p-phenylenevinylene), polyanilines such as polyaniline and poly(N-substituted aniline), polyacetylenes such as polyacetylene polydiacetylene, and polyazulenes such as polyazulene. Among the above, pentacene or polythiophenes are suitably used in this embodiment.

No particular limitation is imposed on the thickness of the organic semiconductor layer to be used in this embodiment insofar as it is within the range where an organic semiconductor layer having desired semiconductor characteristics can be developed according to factors such as the type of the semiconductor material. Particularly, the thickness of the organic semiconductor layer to be formed above the channel region in this embodiment is preferably 1000 nm or less, more preferably in the range from 1 nm to 300 nm, and still more preferably 1 nm to 100 nm.

3. Gate Insulation Layer

Next, the gate insulation layer used in this embodiment will be described. The gate insulation layer used in this embodiment is formed in such a manner that it is laminated on the organic semiconductor layer and is made of an insulation resin material.

The gate insulation layer used in this embodiment will be described in detail.

No particular limitation is imposed on the structure in which the gate insulation layer is formed in this embodiment insofar as it is a structure in which the gate insulation layer is formed in the opening part of the insulation partitioned part in such a manner that the gate insulation layer is laminated on the aforementioned organic semiconductor layer. Particularly, in this embodiment, it is preferable that the gate insulation layer is formed such that the height of the upper surface of the gate insulation layer is the same as the upper surface of the insulation partitioned part. The reason is that if the gate insulation layer is formed in this manner, the gate electrode which will be described later is easily formed on the gate insulation layer when the organic semiconductor device of this embodiment is manufactured.

There is no particular limitation imposed on the thickness of the gate insulation layer to be used in this embodiment insofar as it is in a range where desired insulation ability can be provided to the gate insulation layer in accordance with factors such as the type of the insulation resin material constituting the gate insulation layer. Particularly, in this embodiment, the thickness of the gate insulation layer is preferably in the range from 0.01 μm to 5 μm, more preferably 0.01 μm to 3 μm, and still more preferably 0.01 μm to 1 μm.

Further, no particular limitation is imposed on the insulation resin material constituting the gate insulation layer insofar as it can provide desired insulation ability to the gate insulation layer and it does not impair the performance of the organic semiconductor layer when the gate insulation layer is formed on the organic semiconductor layer in the process of manufacturing an organic semiconductor device according to this embodiment. Examples of the insulation resin material may include acryl type resins, phenol type resins, fluorine type resins, epoxy type resins, cardo-type resins, vinyl type resins, imide type resins and novolac type resins.

4. Gate Electrode

Next, the gate electrode used in this embodiment will be described. The gate electrode used in this embodiment is formed on the aforementioned gate insulation layer.

The gate electrode used in this embodiment will be described.

As mentioned above, the gate electrode used in this embodiment is formed so as to cover the opening part of the insulation partitioned part. Here, in this embodiment, the word “so as to cover the opening part of the insulation partitioned part” means that the area of the gate electrode formed in each opening part is larger than the area of the opening part.

No particular limitation is imposed on the material constituting the gate electrode used in this embodiment insofar as it is an electroconductive material. Examples of the electroconductive material may include metals such as Al, Cr, Au, Ag, Ta, Cu, C, Pt and Ti, and conductive polymer materials such as PEDOT/PSS.

Further, the gate electrode used in this embodiment is formed into a specified pattern on the gate insulation layer which will be described later. No particular limitation is imposed on the pattern of the gate electrode and an optional pattern may be selected and used according to factors such as the uses of the organic semiconductor device of this embodiment.

The gate electrode used in this embodiment is preferably formed in a manner so as to cover the opening part of the insulation partitioned part. This is because when the gate electrode is formed so as to cover the opening part of the insulation partitioned part, the area of the gate electrode formed in each opening part is made larger than the area of the organic semiconductor layer formed in each opening part and an organic semiconductor transistor reduced in off-current can be manufactured.

5. Source Electrode/Drain Electrode

Next, the source electrode and the drain electrode to be used in this embodiment will be described. The source electrode and drain electrode to be used in this embodiment are to be formed on the substrate which will be described later and constitute the channel region.

Though the source electrode and drain electrode used in this embodiment are generally constituted of metal materials, no particular limitation is imposed on the metal material insofar as it is a material having desired conductivity. Examples of these metal materials may include Al, Cr, Au, Ag, Ta, Cu, C, Pt, Ti, Nb, Mo, IZO and ITO. Also, as the material used for the source and drain electrodes to be used in this embodiment, conductive polymers such as PEDOT/PSS may be used.

Here, the source and drain electrodes used in this embodiment are usually made of the same materials.

The source and drain electrodes used in this embodiment are formed into a specified pattern on the substrate which will be described later. No particular limitation is imposed on the pattern of the source and drain electrodes and an optional pattern may be selected and used in accordance with factors such as the uses of the organic semiconductor device of this embodiment.

6. Substrate

Next, the substrate to be used in the organic semiconductor device of this embodiment will be described. The substrate used in this embodiment serves to support the organic semiconductor transistor.

As the substrate used in this embodiment, those having a desired function according to factors such as the use of the organic semiconductor device of this embodiment may be used. As such a substrate, a rigid substrate having no flexibility such as a glass substrate may be used, or a flexible substrate such as a plastic resin film may be used. Although either of these rigid substrate or flexible substrate is used in this embodiment, a flexible substrate is preferably used. This is because if such a flexible substrate is used, the organic semiconductor device of this embodiment can be produced by a Roll-to-Roll process and the organic semiconductor device of this embodiment may be manufactured with better productivity.

Here, examples of the plastic resin may include PET, PEN, PES, PI, PEEK, PC, PPS and PEI.

Also, the substrate used in this embodiment may have a monolayer structure or a structure obtained by laminating plural layers. As the substrate having the structure in which plural layers are laminated, those having, for example, a structure in which barrier layers made of metal materials are laminated on the substrate made of the aforementioned plastic resin may be given as examples. Here, it is pointed out that the substrate made of the plastic resin has an advantage in that the organic semiconductor device of this embodiment is made to be a flexible one, but, on the contrary, has the drawback that the surface of the substrate is easily damaged on forming the source and drain electrodes. However, the use of the substrate produced by laminating barrier layers has an advantage in that the drawback as stated above can be solved even in the case of using a base material made of the plastic resin.

The thickness of the substrate used in this embodiment is usually 1 mm or less, and more preferably in the range from 50 μm to 700 μm.

Here, when the substrate used in this embodiment has a structure in which plural layers are laminated, the thickness means the total thickness of these plural layers.

7. Other Structures

The organic semiconductor device of this embodiment may have other structures besides the aforementioned structures. No particular limitation is imposed on these other structures as long as desired functions can be provided to the organic semiconductor device of this embodiment in accordance with factors such as the uses of the organic semiconductor device of this embodiment. Examples of structures preferably used in this embodiment among these structures may include a passivation layer that is formed on the gate electrode and prevents the organic semiconductor layer from being deteriorated by the effect of moisture and oxygen existing in the air.

There is no particular limitation to the material constituting the passivation layer used in this embodiment insofar as it is resistant to the transmission of moisture and oxygen involved in the air and can prevent the organic semiconductor layer from being deteriorated to a desired extent. Examples of these materials may include water-soluble resins such as PVA and PVP and fluororesins.

No particular limitation is imposed on the structure in which the passivation layer is formed on the organic semiconductor device in this embodiment insofar as it can prevent the organic semiconductor layer, to a desired extent, from being deteriorated in accordance with factors such as the material constituting the passivation layer and to the uses of the organic semiconductor of this embodiment, Particularly, in this embodiment, the passivation layer is preferably formed so as to cover at least the upper surface of the opening part of the insulation partitioned part.

Also, the thickness of the passivation layer to be used in this embodiment is preferably in the range from 0.1 μm to 100 μm, more preferably in a the range from 5 μm to 100 μm, and still more preferably in the range from 10 μm to 100 μm, though depending on factors such as the material constituting the passivation layer.

8. Application of the Organic Semiconductor Device

With regard to the application of the organic semiconductor device of this embodiment, it may be used such as a TFT array substrate of a display device using a TFT system. Examples of such a display device may include a liquid crystal display device, electrophoresis display device and organic EL display device.

9. Manufacturing Method of an Organic Semiconductor Device

No particular limitation is imposed on the manufacturing method of an organic semiconductor device in this embodiment insofar as it is a method capable of producing the organic semiconductor device having the aforementioned structure. As such a method, the methods described in the paragraph “B-1: Manufacturing method of an organic semiconductor device in a first embodiment” which will be described later may be used.

A-2: Organic Semiconductor Device in a Second Embodiment

Organic semiconductor device in a second embodiment will be explained next. The organic semiconductor transistor of this embodiment comprises an organic semiconductor transistor having a bottom gate type structure.

Specifically, an organic semiconductor device of this embodiment comprises: a substrate; a gate electrode formed on the substrate; an insulation partitioned part which is formed on the gate electrode, made of an insulation material, provided with an opening part and has a function as an interlayer-insulation layer; a gate insulation layer which is formed in the opening part of the insulation partitioned part and on the gate electrode, and made of an insulation resin material; an organic semiconductor layer which is formed in the opening part of the insulation partitioned part and on the gate insulation layer, and made of an organic semiconductor material; and a source electrode and a drain electrode which are formed on the organic semiconductor layer, wherein; the insulation partitioned part has a height ranging from 0.1 μm to 1.5 μm.

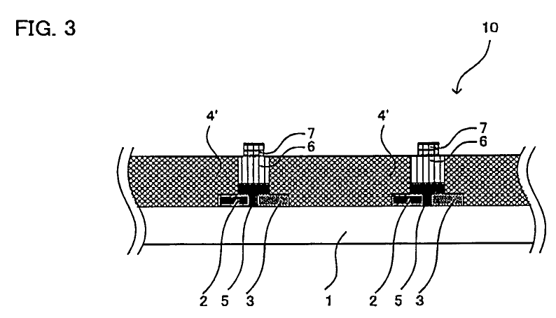

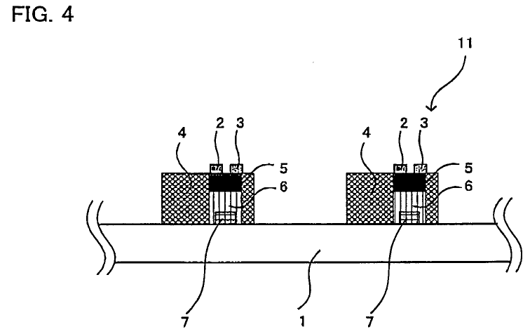

Such an organic semiconductor device in this embodiment will be described with reference to the drawings. FIG. 4 is a schematic sectional view showing an example of the organic semiconductor device of this embodiment. As illustrated in FIG. 4, an organic semiconductor device 11 in this embodiment is provided with: a substrate 1; a gate electrode 7 formed on the substrate 1; an insulation partitioned part 4 which is formed on the gate electrode 7, provided with an opening part and has a function as an interlayer-insulation layer; a gate insulation layer 6 which is formed in the opening part of the insulation partitioned part and on the gate electrode and is made of an insulating resin material; an organic semiconductor layer 5 which is formed in the opening part of the insulation partitioned part 4 and on the gate insulation layer 6 and made of an organic semiconductor material; and a source electrode 2 and a drain electrode 3 formed on the organic semiconductor layer 5.

In an example like this, the organic semiconductor device 11 of this embodiment is characterized by the structure in which the insulation partitioned part 4 has a height ranging from 0.1 μM to 1.5 μm.

According to this embodiment, the gate insulation layer is formed in the opening part of the insulation partitioned part and therefore, a gate insulation layer is selectively formed in the insulation partitioned part by using such as an ink jet method having high productivity in the process of manufacturing an organic semiconductor device of this embodiment.

Further, since the height of the insulation partitioned part is in the rage from 0.1 μm to 1.5 μm in this embodiment, the gate insulation layer can be formed in uniform thickness in the opening part even in the case of forming a gate insulation layer in the opening part by using such as an ink jet method having high productivity. As a result, an organic semiconductor transistor superior in transistor performance can be produced.

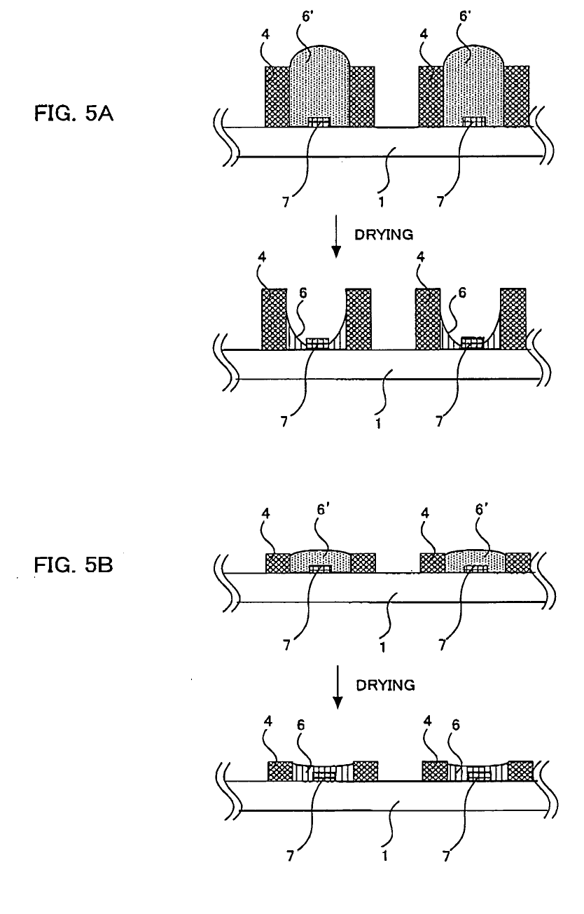

Here, it is described why the gate insulation layer is formed in uniform thickness in the opening part when the height of the insulation partitioned part is in the aforementioned range in this embodiment. FIGS. 5A and 5B are each a schematic view showing an example in the case of forming a gate insulation layer in the opening part of the insulation partitioned part. FIG. 5A shows an example in the case where the height of the insulation partitioned part is high as usual organic semiconductor devices, and FIG. 5B shows an example in the case where the height of the insulation partitioned part is low similarly to the case of this embodiment.

If a gate insulation layer formation coating solution 6′ containing an insulation resin material is coated to the inside of the opening part and then dried when the insulation partitioned part 4 is high as illustrate in FIG. 5A, the gate insulation layer 6 is eventually formed in the manner that the insulation resin material is formed locally on the wall surf ace of the opening part by the effect of a difference in drying speed. As a result, the thickness of the gate insulation layer 6 becomes uneven and it is difficult to form the gate insulation layer 6 having a necessary thickness on the channel region formed by the source electrode 2 and the drain electrode 3. However, if the height of the insulation partitioned part 4′ is reduced as illustrated in FIG. 5B, it is possible to prevent such a phenomenon that the insulation resin material is formed locally on the wall surface of the insulation partitioned part 4 along with the drying of the gate insulation layer coating solution 6′, resulting in that a uniform gate insulation layer 6 can be formed in a necessary thickness above the channel region.

From this fact, this embodiment can provide a manufacturing method of an organic semiconductor device, which is provided with an organic semiconductor transistor having good transistor performance and can be produced with high productivity.

The organic semiconductor device in this embodiment is provided with at least the substrate, the gate electrode, the insulation partitioned part, the gate insulation layer, the organic semiconductor layer, the source electrode and the drain electrode.

Each of the structures to be used in the organic semiconductor device of this embodiment will be described.

1. Insulation Partitioned Part

First, the insulation partitioned part to be used in this embodiment will be described. The insulation partitioned part to be used in this embodiment is made of an insulating material and is formed such that its opening part is disposed above the gate electrode. Also, the insulation partitioned part used in this embodiment is characterized by the structure in which the height of the insulation partitioned part is in the range from 0.1 μm to 1.5 μm. The insulation partitioned part to be used in this embodiment also has a function as an interlayer-insulation layer.

The height of the insulation partitioned part used in this embodiment is in the range from 0.1 μm to 1.5 μm. The reason why the height of the insulation partitioned part is limited to this range is that if the height exceeds the range, the gate insulation layer to be formed in the opening part is disposed locally in the vicinity of the wall surface of the opening part and therefore, the performance of the organic semiconductor transistor to be formed is damaged. Also, if the height is below the range, there is the case where the gate insulation layer to be formed in the opening part becomes so thin that no desired ability can be developed. Further, it the thickness is below the range, there is the case where, when liquid repellency is imparted to the insulation partitioned part used in this embodiment, it is difficult to impart sufficient liquid repellency.

Here, the height of the insulation partitioned part to be used in this embodiment is preferably in the range from 0.5 μm to 1.5 μm, and more preferably in a range from 1.0 μm to 1.5 μm, though no particular limitation is imposed on it insofar as it is in the aforementioned range.

The insulation partitioned part used in this embodiment is the same as that described in the paragraph “A-1: Organic semiconductor device in a first embodiment” except that its opening part is disposed on the gate electrode which will be described later, and therefore detailed descriptions of the insulation partitioned part are omitted here.

2. Gate Insulation Layer

Next, the gate insulation layer used in this embodiment will be described. The gate insulation layer used in this embodiment is made of an insulation resin material and formed in the opening part of the aforementioned insulation partitioned part and on the gate electrode which will be described later.

The gate insulation layer used in this embodiment is the same as that described in the paragraph “A-1: Organic semiconductor device in a first embodiment” except that it is formed on the gate electrode, and therefore detailed descriptions of the gate insulation layer are omitted here.

3. Organic Semiconductor Layer

Next, the organic semiconductor layer used in this embodiment will be described. The organic semiconductor layer used in this embodiment is formed in the opening part of the aforementioned insulation partitioned part and on the gate insulation layer. Also, the organic semiconductor layer used in this embodiment is made of an organic semiconductor material.

Here, since the opening part of the insulation partitioned part is formed in such a manner that it is disposed on the gate electrode which will be described later, the area of the organic semiconductor layer used in this embodiment is inevitably smaller than the area of the gate electrode which will be described later.

The organic semiconductor layer used in this embodiment is the same as that described in the paragraph “A-1: Organic semiconductor device in a first embodiment” except that it is formed on the gate insulation layer, and therefore detailed descriptions of the organic semiconductor layer are omitted here.

4. Gate Electrode

Next, the gate electrode used in this embodiment will be described. The gate electrode used in this embodiment is formed on the substrate.

The gate electrode used in this embodiment is usually made of a conductive material. No particular limitation is imposed on the conductive material insofar as it has desired conductivity. As such a conductive material, those described in, for example, the paragraph “A-1: Organic semiconductor device in a first embodiment” may be used.

Further, the gate electrode used in this embodiment is formed into a specified pattern on the substrate which will be described later. No particular limitation is imposed on the pattern of the gate electrode and a desired pattern may be selected and used in accordance with factors such as the uses of the organic semiconductor device of this embodiment.

5. Source Electrode/Drain Electrode

Next, the source and drain electrodes to be used in this embodiment will be described. The source and drain electrodes used in this embodiment are to be formed on the aforementioned organic semiconductor layer.

Next, the source and drain electrodes used in this embodiment is usually made of a conductive material. No particular limitation is imposed on the conductive material insofar as it can form source and drain electrodes on the organic semiconductor layer without impairing the semiconductor characteristics of the organic semiconductor layer in the process of producing the organic semiconductor device of this embodiment. As such a conductive material, the same materials that are described as the material constituting the source and drain electrodes in, for example, the paragraph “A-1: Organic semiconductor device in a first embodiment” may be used.

The source and drain electrodes used in this embodiment are usually constituted of the same metal material.

Also, the source and drain electrodes used in this embodiment are formed into a specified pattern on the organic semiconductor layer. There is no particular limitation to the patterns of the source and drain electrodes and an optional pattern is selected and used in accordance with factors such as the uses of the organic semiconductor device of this embodiment.

6. Substrate

Next, the substrate used in this embodiment will be described. The substrate used in this embodiment serves to support the aforementioned organic semiconductor transistor.

Here, the substrate used in this embodiment is the same as that described in the paragraph “A-1: Organic semiconductor device in a first embodiment” and therefore, descriptions of the substrate are omitted here.

7. Other Structures

The organic semiconductor device of this embodiment may have other structures besides the structures mentioned above. No particular limitation is imposed on these other structures insofar as they can add desired functions in accordance with factors such as the uses of the organic semiconductor device of this embodiment. Examples of other structures preferably used in this embodiment among these other structures may include a passivation layer which is formed on the organic semiconductor layer and prevents the organic semiconductor layer from being deteriorated by the effects of moisture and oxygen present in the air. Here, the passivation layer used in this embodiment is the same as that described in the paragraph “A-1: Organic semiconductor device in a first embodiment” and therefore, descriptions of the passivation layer are omitted here.

8. Application of the Organic Semiconductor Device

With regard to the application of the organic semiconductor device of this embodiment, it may be used as a TFT array substrate of a display device using a TFT system. Examples of such a display device may include a liquid crystal display device, electrophoresis display device and organic EL display device.

9. Manufacturing Method of an Organic Semiconductor Device

No particular limitation is imposed on the manufacturing method of an organic semiconductor device in this embodiment insofar as it is a method capable of producing the organic semiconductor device having the aforementioned structure. As such a method, the methods described in the paragraph “B-2: Manufacturing method of an organic semiconductor device in a second embodiment” which will be described later may be used.

B. Manufacturing Method of an Organic Semiconductor Device

Next, the manufacturing method of an organic semiconductor device of the present invention will be described. The manufacturing method of an organic semiconductor device according to the present invention may be classified into: a first embodiment of manufacturing an organic semiconductor device provided with an organic semiconductor transistor having a top gate type structures and a second embodiment of manufacturing an organic semiconductor device provided with an organic semiconductor transistor having a bottom gate type structure.

The manufacturing method of an organic semiconductor device according to the present invention will be described in each embodiment separately.

B-1: Manufacturing Method of an Organic Semiconductor Device in a First Embodiment

First, the manufacturing method of an organic semiconductor in a first embodiment of the present invention will be described. The manufacturing method of an organic semiconductor device in this embodiment is to manufacture an organic semiconductor device having a top gate type organic semiconductor transistor.

Specifically, a manufacturing method of an organic semiconductor device of this embodiment comprises: a source/drain electrode formation step of using a substrate to form a source electrode and a drain electrode on the substrate; an insulation partitioned part formation step of forming an insulation partitioned part made of an insulation material on the source electrode and the drain electrode formed in the source/drain electrode formation step such that an opening part of the insulation partitioned part is disposed above a channel region formed by the source electrode and the drain electrode and a height of the insulation partitioned part is in the range from 0.1 μm to 1.5 μm; an organic semiconductor layer formation step of forming an organic semiconductor layer made of an organic semiconductor material, in the opening part of the insulation partitioned part formed in the insulation partitioned part formation step and on the source electrode and the drain electrode; a gate insulation layer formation step of forming a gate insulation layer made of an insulation resin material on the organic semiconductor layer formed in the organic semiconductor layer formation step; and a gate electrode formation step of forming a gate electrode on the gate insulation layer formed in the gate insulation layer formation step.

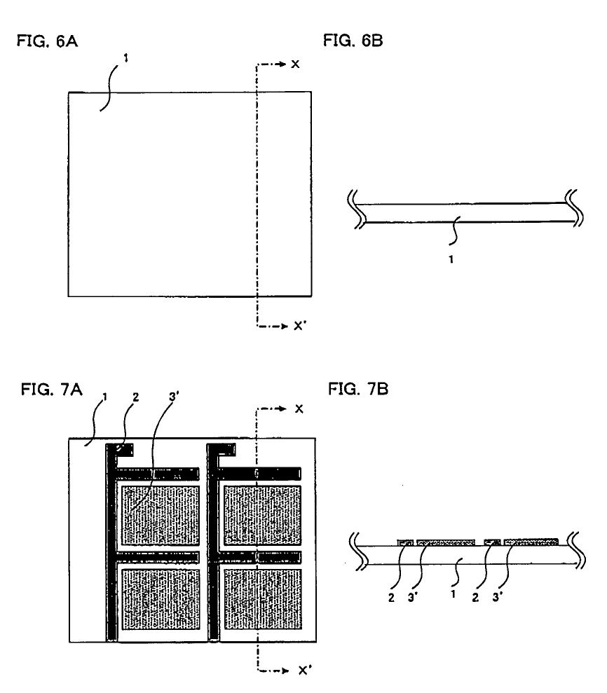

The manufacturing method of an organic semiconductor device in this embodiment will be described with reference to the drawings. FIGS. 6 to 11 are schematic views showing an example of the manufacturing method of an organic semiconductor device in this embodiment. FIGS. 6B to 11B are each a sectional views along the line X-X′ in FIGS. 6A to 11A.

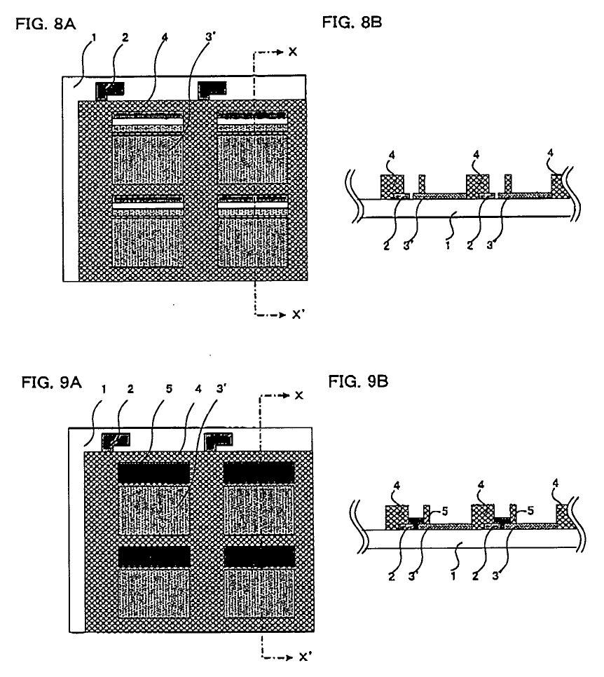

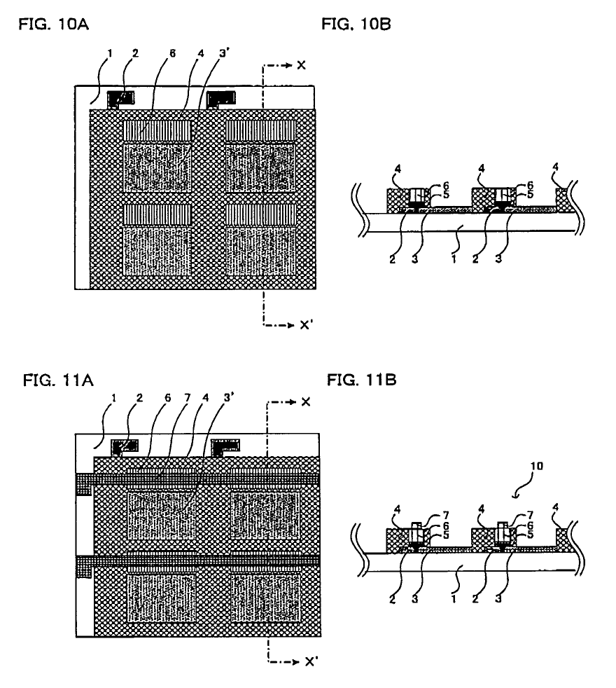

As illustrated in FIGS. 6 to 11, the manufacturing method of an organic semiconductor device according to this embodiment involves: a source/drain electrode formation step of using a substrate 1 (FIGS. 6A to 6B) to form source and drain electrodes 2 and 3′ on the substrate 1 (FIGS. 7A to 7B); an insulation partitioned part formation step of forming an insulation partitioned part 4 made of an insulating material on the source and drain electrodes 2 and 3′ such that the opening part of the insulation partitioned part is formed above the channel region formed by the source and drain electrodes 2 and 3′ which are formed in the source and drain electrode formation step (FIGS. 8A to 8B): an organic semiconductor layer formation step of forming an organic semiconductor layer 5 made of an organic semiconductor material in the opening part of the insulation partitioned part 4 formed in the insulation partitioned part formation step and on the source electrode 2 and the drain electrode 3′ (FIGS. 9A to 9B); a gate insulation layer formation step of forming a gate insulation layer 6 made of an insulation resin material on the organic semiconductor layer 5 formed in the organic semiconductor layer formation step (FIGS. 10A to 10B); and a gate electrode formation step of forming a gate electrode in such a manner as to cover the opening part of the insulation partitioned part (FIGS. 11A to 11B).

In such an example, the manufacturing method of an organic semiconductor device in this embodiment is characterized by the structure in which the height of the insulation partitioned part 4 formed in the insulation partitioned part formation step is in the range from 0.1 μm to 1.5 μm.

The drain electrode 3′ shown in respective FIGS. 6 to 11 is integrated with a pixel electrode.

According to this embodiment, the height of the insulation partitioned part formed in the insulation partitioned part formation step is in the range from 0.1 μm to 1.5 μm, whereby the organic semiconductor layer can be formed uniformly in the opening part in the organic semiconductor layer formation step.

Consequently, this embodiment enables the production of an organic semiconductor device provided with an organic semiconductor transistor having good transistor performance with high productivity.

The reason why the organic semiconductor layer can be formed-uniformly in the opening part in the organic semiconductor layer formation step when the height of the insulation partitioned part formed in the insulation partitioned part formation step is limited to the range from 0.1 μm to 1.5 μM is the same as that described in the paragraph “A-1: Organic semiconductor device in a first embodiment” and therefore, descriptions of the reason are omitted here.

The manufacturing method of an organic semiconductor device according to this embodiment comprises at least the source/drain electrode formation step, the insulation partitioned part formation step, the organic semiconductor layer formation step, the gate insulation layer formation step and the gate electrode formation step.

Each step used the manufacturing method of an organic semiconductor device in this embodiment will be described.

1. Source/Drain Electrode Formation Step

First, the source/drain electrode formation step used in this embodiment will be described. This step is a step of using a substrate to form source and drain electrodes on the substrate.

In this step, there is no particular limitation is imposed on the method of forming the source and drain electrodes on the substrate insofar as it can form the source electrode and the drain electrode into a desired pattern. Examples of such a formation method may include: a method in which pattern-like source and drain electrodes are formed directly on the substrate (first method), and a method in which a conductive thin layer is formed on the entire surface of the substrate and then, the conductive thin layer is etched pattern-wise to form source and drain electrodes (second method). In this step, either of these methods may be used. Among these methods, the second method is preferably used. This is because the use of such a method enables the formation of further finely-patterned source and drain electrodes.

No particular limitation is imposed on the method of etching the conductive thin layer pattern-wise in the second method insofar as the etching can be performed to make the conductive thin layer into a desired pattern. Examples of such an etching method may include a lithographic method using a resist material and a laser abrasion method. Either of these methods may be preferably used in this step. Among these methods, the lithographic method using a resist material is most preferably used. This is because finely-patterned source and drain electrodes can be easily produced by the lithographic method. This is also because this method makes it possible to carry out this step as a continuous process.

As the resist material, for example, a photoresist, screen resist or EB resist may be used.

No particular limitation is imposed on the second method of forming the conductive thin layer on the substrate insofar as it is a method in which a conductive thin layer having uniform thickness can be formed. Methods such as a vacuum vapor deposition method, usually known as the methods of forming metal thin films, may be used.

Here, the material for the conductive thin layer is the same as those described as the metal materials for the source and drain electrodes in the paragraph “A-1: Organic semiconductor device in a first embodiment” and therefore, descriptions of these materials are omitted here.

The drain electrode formed in this step may be integrated with a pixel electrode.

Here, the substrate used in this embodiment is the same as that described in the paragraph “A-1: Organic semiconductor device in a first embodiment” and therefore, descriptions of the substrate are omitted here.

2. Insulation Partitioned Part Formation Step

Next, the insulation partitioned part formation step used in this embodiment will be described. In this step, an insulation partitioned part which is made of an insulation material and has a height range from 0.1 μm to 1.5 μm is formed on the source and drain electrodes formed in the source/drain electrode formation step such that its opening part is disposed above the channel region formed by the source and drain electrodes.

This step is characterized by the structure of the insulation partitioned part in which the height of the insulation partitioned part formed in this step is in the range from 0.1 μm to 1.5 μm. The reason why the height of the insulation partitioned part is limited to this range is that if the height exceeds the range, the organic semiconductor layer to be formed in the opening part in the organic semiconductor layer formation step is disposed locally in the vicinity of the wall surface of the opening part and therefore, the performance of the organic semiconductor transistor to be formed is damaged. Also, if the height is below the range, there is the case where the organic semiconductor layer formed in the opening part in the semiconductor layer formation step which will be described later becomes so thin that no desired ability can be developed. Further, if the thickness is below the range, there is the case where when liquid repellency is imparted to the insulation partitioned part to be formed in this step, it is difficult to impart sufficient liquid repellency and there is therefore the case where it becomes difficult to coat ink jet to the inside of the opening part.

Here, the height of the insulation partitioned part to be formed in this step is preferably in the range from 0.1 μm to 1.0 μm, and more preferably in the range from 0.1 μm to 0.5 μm, though no particular limitation is imposed on it insofar as it is in the above range.

In this step, there is no particular restriction on the method of forming the insulation partitioned part insofar as it is a method that can form an insulation partitioned part having a desired pattern on the source and drain electrodes. Examples of such a method may include a photolithographic method, micro-contact printing method, ink jet method and printing methods such as a screen printing method, flexo printing method, gravure printing method and gravure-offset printing method. Among these methods, a photolithographic method is preferably used.

The insulation material used in this step is the same as that described in the paragraph “A-1: Organic semiconductor in a first embodiment”, and therefore, descriptions of the insulation material are omitted here.

3. Organic Semiconductor Layer Formation Step

Next, the organic semiconductor layer formation step used in this embodiment will be described. This is a step of forming an organic semiconductor layer made of an organic semiconductor material in the opening part of the insulation partitioned part formed in the insulation partitioned part formation step and on the source and drain electrodes.

No particular limitation is imposed on the method of forming the organic semiconductor layer in this step insofar as it is a method enabling the formation of an organic semiconductor layer in a desired thickness in the opening part of the insulation partitioned part in accordance with factors such as the type of the organic semiconductor material used in this step. Examples of such a method may include a method in which, on the premise that the organic semiconductor material is soluble in a solvent, the organic semiconductor material is dissolved in a solvent to prepare an organic semiconductor layer formation coating solution and then, this coating solution is coated. In this case, examples of the coating method may include an ink jet method, spin coating method, die coating method, roll coating method, bar coating method, LB method, dip coating method, spray coating method, blade coating method, screen printing, flexo-printing, gravure offset printing and casting method. When the organic semiconductor material is insoluble in a solvent, on the other hand, examples of coating method may include a method in which a dry process such as vacuum vapor deposition method is used to coat the organic semiconductor layer formation coating solution. Among these methods, the method in which the organic semiconductor layer formation coating solution is coated is preferably used in this step. Particularly, it is most preferable to use a method in which the organic semiconductor layer formation coating solution is coated only to the inside of the opening part of the insulation partitioned part by the ink jet method. This is because, in this step, the organic semiconductor layer can be formed with higher efficiency by the method, with the result that an organic semiconductor device can be formed further efficiently. Also, this is because since, in this embodiment, the height of the insulating partitioned part formed in the insulation partitioned part formation step is in the range of 0.1 μm to 1.5 μm, an organic semiconductor layer having uniform thickness can be formed even if an ink jet method is used.

Any organic semiconductor material may be used as the organic semiconductor material used in this step without any particular limitation insofar as it can impart desired semiconductor characteristics to the organic semiconductor layer to be formed in this step in accordance with factors such as the uses of the organic semiconductor device. Examples of such an organic semiconductor material are the same as those described in the paragraph “A-1. Organic semiconductor device in a first embodiment” and therefore, descriptions of the organic semiconductor material will be omitted here.

4. Gate Insulation Layer Formation Step

Next, the gate insulation layer formation step used in this embodiment will be described. This is a step of forming a gate insulation layer made of an insulation resin material on the organic semiconductor layer formed in the organic semiconductor layer formation step.

In this step, no particular limitation is imposed on the method of forming the gate insulation layer insofar as it is a method-capable of forming a gate insulation layer having desired insulation ability on the organic semiconductor layer. Examples of such a method may include: a method in which a gate insulation layer formation coating solution prepared by dissolving an insulation resin material constituting the gate insulation layer in a solvent is coated (first method); a method in which a gate insulation layer formation composition obtained by melting an insulation resin material constituting the gate insulation layer is coated to the organic semiconductor layer (second method); and a method in which a gate insulation layer forming layer formation coating solution obtained by dissolving a monomer compound of an insulation resin material constituting the gate insulation layer in a solvent is coated to the organic semiconductor layer to form a gate insulation layer forming layer and then, the monomer compound contained in the gate insulation layer forming layer is polymerized (third method). Among these methods, the first method is more preferably used though either of these methods may be preferably used in this step.

As the gate insulation layer formation coating solution used in the first method, one using a solvent which does not erode the organic semiconductor layer is generally used. More specifically, as the solvent, those using water or a fluorine type solvent are preferably used. This is because the gate insulation layer formation coating solution using such a solvent scarcely erodes the organic semiconductor layer when coated to the organic semiconductor layer.

As the fluorine solvent, a perfluoro type solvent, which is a solvent obtained by substituting all hydrogen atoms of hydrocarbons such as alkanes or alkenes with fluorine atoms, is preferably used. Examples of the perfluoro type solvent may include perfluoromethylcyclohexane, perfluoro-1,3-dimethylcyclohexane, perfluoro-2-methyl-2-pentene, perfluorodecaline, 1,1,1,2,2,3,3,4,4,5,5,6,6-tridecafluoro-8-iodooctane, 3,3,4,4,5,5,6,6,7,7,8,8,8-tridecafluoro-1-octene and 3,3,4,4,5,5,6,6,7,7,8,8,8-tridecafluoro-1-octanol.

Also, the fluorine type solvent used in this step may be a solvent constituted of a single fluorine solvent or a mixture solvent prepared by mixing plural fluorine type solvents.

No particular limitation is imposed on the insulation resin material used for the gate insulation layer formation coating solution insofar as it is soluble in a desired concentration in the solvent. When water is used as the solvent, PVA, PVP or the like is used. When a fluorine type solvent is used as the solvent, a fluorine type resin is used.

Examples of the coating method of coating the gate insulation layer formation coating solution in the first method may include an ink jet method, screen printing method, pad printing method, flexo printing method, micro-contact printing method, gravure printing method, offset printing method and gravure-offset printing method. In this step, among these methods, a method is preferably used in which the gate insulation layer formation coating solution is coated only to the opening part of the insulation partitioned part by using the ink jet method or screen printing method.

5. Gate Electrode Formation Step

Next, the gate electrode formation step used in this embodiment will be described. This is a step of forming a gate electrode on the gate insulation layer formed in the gate insulation layer formation step.

No particular limitation is imposed on the method of forming a gate electrode in this step insofar as it is a method capable of forming a gate electrode into a desired pattern in such a manner as to cover the opening part of the insulation partitioned part. Examples of such a method may include: a method in which a gate electrode formation coating solution containing a metal colloid such as an Ag colloid is coated pattern-wise to the gate insulation layer by a method such as an ink j et method, and a method in which a metal paste such as an Ag paste is coated pattern-wise to the gate insulation layer by a method such as a screen printing method, flexo printing method, gravure offset printing method, or micro-contact printing method.

6. Other Steps

The manufacturing method of an organic semiconductor device in this embodiment may involve other steps besides the foregoing steps. No particular limitation is imposed on these other steps insofar as they respectively impart desired functions to the organic semiconductor device produced by the manufacturing method of this embodiment. As examples preferably used in this embodiment among these other steps, a pixel electrode formation step of forming pixel electrodes at desired positions and a passivation layer formation step of forming a passivation layer on the gate electrode can be cited.

7. Organic Semiconductor Device

The organic semiconductor device produced in this embodiment is provided with a top gate type organic semiconductor transistor on a substrate. The organic semiconductor device like this is the same as that described in the paragraph “A-1; Organic semiconductor device” and therefore, descriptions of the device are omitted.

B-2; Manufacturing Method of an Organic Semiconductor Device in a Second Embodiment

Next, the manufacturing method of an organic semiconductor in a second embodiment of the present invention will be described. The manufacturing method of an organic semiconductor device in this embodiment is to manufacture an organic semiconductor device having a bottom gate type organic semiconductor transistor.

Specifically, a manufacturing method of an organic semiconductor device of this embodiment comprises: a gate electrode formation step of using a substrate to form a gate electrode on the substrate; an insulation partitioned part formation step of forming an insulation partitioned part on the gate electrode formed in the gate electrode formation step such that a height of the insulation partitioned part is in the range from 0.1 μm to 1.5 μm and an opening part of the insulation partitioned part is disposed above the gate electrode; a gate insulation layer formation step of forming a gate insulation layer made of an insulation resin material, in the opening part of the insulation partitioned part formed in the insulation partitioned part formation step and on the gate electrode; an organic semiconductor layer formation step of forming an organic semiconductor layer made of an organic semiconductor material on the gate insulation layer formed in the gate insulation layer formation step; and a source/drain electrode formation step of forming a source electrode and a drain electrode on the organic semiconductor layer formed in the organic semiconductor layer formation step.

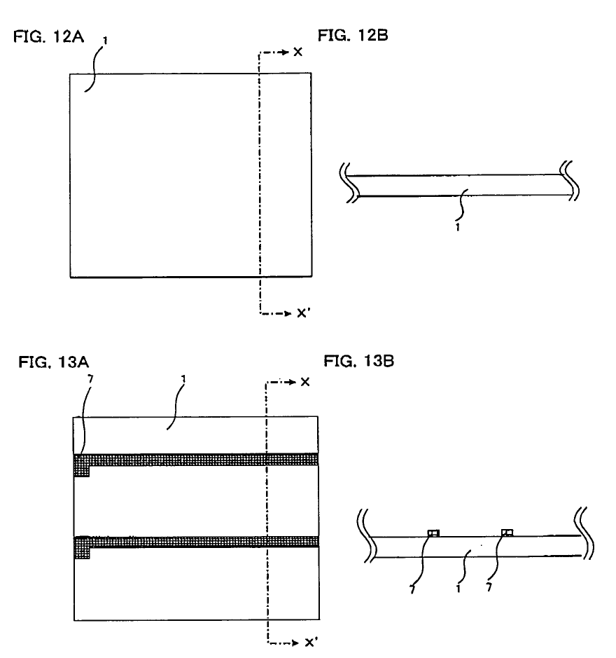

The manufacturing method of an organic semiconductor device in this embodiment will be described with reference to the drawings. FIGS. 12 to 17 are each a schematic views showing an example of the manufacturing method of an organic semiconductor device in this embodiment. FIGS. 12B to 17B are sectional views along the line X-X′ in FIGS. 12A to 17A.

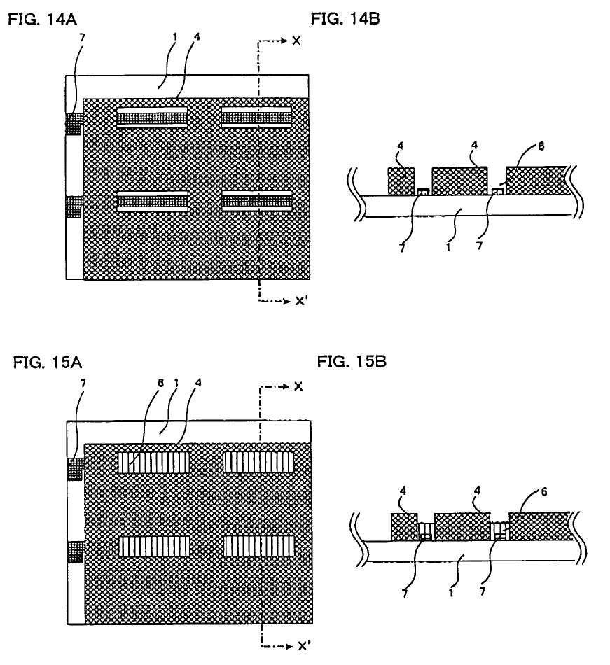

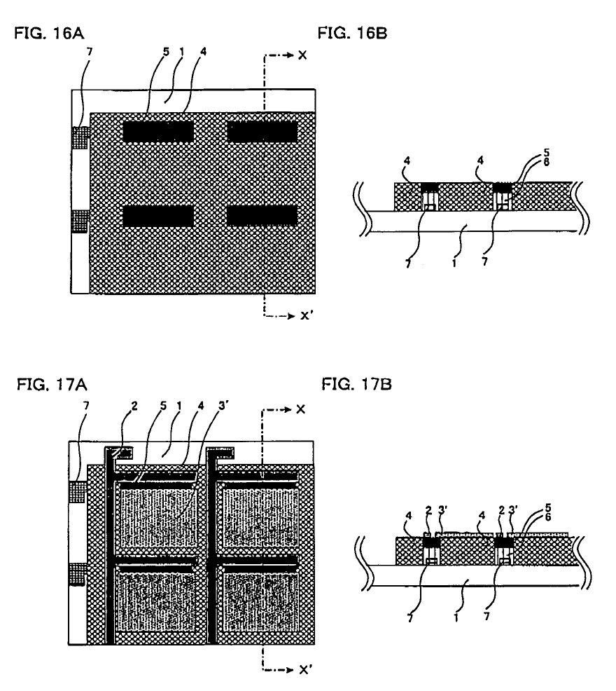

As illustrated in FIGS. 12 to 17, the manufacturing method of an organic semiconductor device according to this embodiment involves: a gate electrode formation step of using a substrate 1 (FIGS. 12A to 12B) to form a gate electrode 7 on the substrate 1 (FIGS. 13A to 13B); an insulation partitioned part formation step of forming an insulation partitioned part on the gate electrode 7 formed in the gate electrode formation step (FIGS. 14A to 14B) such that the opening part of the insulation partitioned part is disposed above the gate electrode; a gate insulation layer formation step of forming a gate insulation layer 6 in the opening part of the insulation partitioned part 4 formed in the insulation partitioned part formation step and on the gate electrode 7 (FIGS. 15A to 15B); an organic semiconductor layer formation step of forming an organic semiconductor layer 5 made of an organic semiconductor material on the gate insulation layer 6 formed in the gate insulation layer formation step (FIGS. 16A to 16B); and a source/drain electrode formation step of forming the source and drain electrodes 2 and 3′ on the organic semiconductor layer 5 formed on the organic semiconductor layer formation step (FIGS. 17A to 17B).

In such an example, the manufacturing method of an organic semiconductor device in this embodiment is characterized by the structure in which the height of the insulation partitioned part 4 formed in the insulation partitioned part formation step is in the range from 0.1 μm to 1.5 μm.

The drain electrode 3′ shown in respective FIGS. 12 to 17 is integrated with a pixel electrode.

According to this embodiment, the height of the insulation partitioned part formed in the insulation partitioned part formation step is in the range from 0.1 μm to 1.5 μm, whereby the gate insulation layer can be formed uniformly in the opening part in the gate insulation layer formation step.

Consequently, this embodiment enables the production of an organic semiconductor device provided with an organic semiconductor transistor having good transistor performance with high productivity.

The reason why the organic semiconductor layer can be formed uniformly in the opening part in the organic semiconductor layer formation step when the height of the insulation partitioned part formed in the insulation partitioned part formation step is limited to the range from 0.1 μm to 1.5 μm is the same as that described in the paragraph “A-2: Organic semiconductor device in a second embodiment” and therefore, descriptions of the reason are omitted here.

The manufacturing method of an organic semiconductor device according to this embodiment comprises at least the gate electrode formation step, the insulation partitioned part formation step, the gate insulation layer formation step, the organic semiconductor layer formation step and the source/drain electrode formation step.

Each step used in the manufacturing method of an organic semiconductor device in this embodiment will be described.

1. Gate Electrode Formation Step

The gate electrode formation step is a step of using a substrate to form a gate electrode on the substrate.

No particular limitation is imposed on the method of forming a gate electrode on the substrate in this step insofar as it is a method capable of forming a gate electrode into a desired pattern. Such a method is the same as that described as the method of forming the source and drain electrodes in the paragraph “B-1: Manufacturing method of an organic semiconductor device in a first embodiment” and therefore, descriptions of this method are omitted here.

2. Insulation Partitioned Part Formation Step

The insulation partitioned part formation step used in this embodiment is a step of forming an insulation partitioned part which is disposed on the gate electrode formed on the gate electrode formation step and is provided with an opening part disposed above the gate electrode. This step is characterized by the structure of the insulation partitioned part in which the height of the insulation partitioned part formed in this step is in the range from 0.1 μm to 1.5 μm.

This step is characterized by the structure of the formed insulation partitioned part having a height ranging from 0.1 μm to 1.5 μm. The reason why the height of the insulation partitioned part is limited to this range is that if the height exceeds the range, the gate insulation layer to be formed in the opening part in the gate insulation layer formation step which will be described later is disposed locally in the vicinity of the wall surface of the opening part and therefore, the performance of the organic semiconductor transistor to be formed is damaged. It the height is below the range, there is the case where the gate insulation layer to be formed in the opening part in the gate insulation layer formation step which will be described later becomes so thin that no desired ability can be developed. Further, if the thickness is below the range, there is the case where when liquid repellency is imparted to the insulation partitioned part to be formed in this step, it is difficult to impart sufficient liquid repellency.

Here, the height of the insulation partitioned part to be formed in this embodiment is preferably in the range from 0.5 μm to 1.5 μm, and more preferably in the range from 1.0 μm to 1.5 μm, though no particular limitation is imposed on it in so far as it is in the above range.

Here, the method of forming the insulation partitioned part in this step is the same as the method described in the paragraph “B-1: Manufacturing method of an organic semiconductor device in a first embodiment” except that the insulation partitioned part is formed on the gate electrode and therefore, descriptions of the method are omitted here.

3. Gate Insulation Layer Formation Step

The gate insulation layer formation step used in this embodiment is a step of forming a gate insulation layer made of an insulation resin material in the opening part of the insulation partitioned part formed in the insulation partitioned part formation step and on the gate electrode.

Here, as the method of forming the gate insulation layer in this step, the same method that is described in the paragraph “B-1: Manufacturing method of an organic semiconductor device in a first embodiment” except that the gate insulation layer is formed on the gate electrode may be used. In this step, among these methods, a method is preferably used in which an ink jet method is used to coat the gate insulation layer formation coating solution only to the inside of the opening part of the insulation partitioned part by an ink jet method. This is because this method enables the formation of the gate insulation layer with high efficiency in this step, with the result that an organic semiconductor device can be manufactured further efficiently. Also, since the height of the insulation partitioned part formed in the insulation partitioned part formation step is in the range from 0.1 μm to 1.5 μm in this embodiment, a gate insulation layer having uniform thickness can be formed even if an ink jet method is used in this step.

4. Organic Semiconductor Layer Formation Step

The organic semiconductor layer formation step used in this embodiment is a step of forming an organic semiconductor layer made of an organic semiconductor material on the gate insulation layer formed in the gate insulation layer formation step.

Here, the method of forming the organic semiconductor layer in this step is the same as the method described in the paragraph “B-1: Manufacturing method of an organic semiconductor device in a first embodiment” except that the organic semiconductor layer is formed on the gate electrode layer and therefore, descriptions of the method are omitted here.

5. Source/Drain Electrode Formation Step

Next, the source and drain electrodes to be used in this embodiment will be described. In this step, the source and drain electrodes are formed on the organic semiconductor layer formed in the organic semiconductor layer formation step.

There is no particular limitation is imposed on the method of forming the source and drain electrodes as long as source and drain electrodes having a desired pattern are formed and without eroding the organic semiconductor layer.

Here, such a method is the same as the method described as the method used to form the gate electrode in the paragraph “B-1; Manufacturing method of an organic semiconductor device in a first embodiment” and therefore, descriptions of the method are omitted here.

6. Other Steps

The manufacturing method of an organic semiconductor device in this embodiment may involve other steps besides the foregoing steps. No particular limitation is imposed on these other steps insofar as they respectively impart desired functions to the organic semiconductor device produced by the manufacturing method of this embodiment. As examples preferably used in this embodiment among these other steps, a pixel electrode formation step of forming pixel electrodes at desired positions and a passivation layer formation step of forming a passivation layer on the gate electrode can be cited.

7. Organic Semiconductor Device

The organic semiconductor device produced in this embodiment is provided with a bottom gate type organic semiconductor transistor on a substrate. The organic semiconductor device like this is the same as that described in the paragraph “A-2: Organic semiconductor device in a second embodiment” and therefore, descriptions of the device are omitted.

C. Organic Transistor Array

Next, an organic transistor array according to the present invention will be described. As mentioned above, the organic transistor array of the present invention is characterized by the use of the organic semiconductor device according to the present invention, wherein plural numbers of the organic semiconductor transistors are formed on the substrate. The organic transistor array of the present invention has an advantage in that it is superior in on-off ratio since the organic semiconductor device according to the present invention is used.

The organic transistor array of the present invention comprises the organic semiconductor device according to the present invention wherein plural organic semiconductor transistors are formed on a substrate. In the present invention, the structure of the organic transistor array in which plural numbers of the organic semiconductor transistors are formed may be properly determined according to factors such as the application of the organic transistor array of the present invention without any particular limitation.

The organic semiconductor transistor used in the organic transistor array of the present invention is the same as that described in the paragraph “A. Organic semiconductor device” and detailed descriptions of the organic transistor are therefore omitted here.

D. Display

Next, a display according to the present invention will be described. As mentioned above, the display of the present invention is characterized by the use of the organic transistor array according to the present invention. The display of the present invention has an advantage in that it has an excellent display performance.

Any display may be used as the display of the present invention without any particular limitation insofar as it has a structure in which the organic transistor array according to the present invention is used and each pixel contributing to image display is switched by each organic semiconductor transistor included in the organic transistor array. Examples of the display having such a structure may include liquid crystal display devices, electrophoresis display devices and organic EL display devices. The display devices typified by these examples are the same as those usually known in the fields concerned except that the organic transistor array is used in place of a conventional TFT array, and detailed descriptions of the display device are omitted here.

Also, the organic transistor array used in the present invention is the same as that described in the paragraph “C Organic transistor array” and descriptions of the organic transistor array are omitted here.

The present invention is not limited to the above embodiments. These embodiments are examples and whatever has substantially the same structure and produces the same action effect as the technical spirit described in the claim of the present invention is embraced by the technical scope of the present invention.

### EXAMPLES

Next, the present invention will be described in more detail by way of examples and comparative examples.

### 1. Example 1

In this embodiment, an organic semiconductor device provided with an organic semiconductor transistor having a top gate type structure was manufactured.

(1) Source/Drain Electrode/Data Line Formation Step

A glass substrate which had a size of 150 mm×150 mm×0.7 mm having a film of ITO 300 nm in thickness formed on the entire surface thereof by a sputtering method was prepared. The substrate was coated with a photoresist (positive type) by spin coating. The spin coating at this time was carried out at 1800 rpm for 10 seconds. Then, the substrate was dried at 100° C. for one minute and then subjected to pattern-exposure at an intensity of 50 mJ/cm².

Next, the resist of the exposed part was developed and then the substrate was dried at 200° C. for 60 minutes in an oven. Then, ITO at parts in which no resist was present was etched to form source and drain electrodes and Data Line. When the formed source and drain electrodes were observed by a reflection type optical microscope, the inter-electrode distance (channel length) between the source and drain electrodes was 50 μm.

(2) Insulation Partitioned Part Formation Step

Next, the substrate was coated with an acryl type resin (negative) by spin coating. The spin coating at this time was carried out at 1400 rpm for 20 seconds. Then, the substrate was dried at 100° C. for 2 minutes and then subjected to pattern exposure at an intensity of 50 mJ/cm². Next, the resist of the unexposed part was developed and then the substrate was dried at 20° C. for 60 minutes in an oven to form an insulation partitioned part. At this time, the height of the formed insulation partitioned part was 1.5 μm.

The patterning of the insulation partitioned part was carried out so as to open only the channel formation region.

(3) Formation of an Organic Semiconductor Layer

A coating solution obtained by dissolving an organic semiconductor material (polythiophene) in a solid concentration of 0.2 wt % in a trichlorobenzene solvent was coated pattern-wise to the inside of the insulation partitioned part by an ink jet method. Thereafter, the coating layer was dried at 200° C. for 10 minutes in a N₂ atmosphere by using a hot plate to form an organic semiconductor layer. The thickness of the formed organic semiconductor layer was 0.1 μm.

(4) Gate insulation layer formation step A coating solution obtained by dissolving PVP (polyvinyl phenol) in a solid concentration of 10 wt % in a n-hexyl alcohol solvent was coated pattern-wise to the inside of the insulation partitioned part by an ink jet method. After that, the substrate was dried at 100° C. for 5 minutes and then at 200° C. for 30 minutes on a hot plate, to form a gate insulation layer. The film thickness of the formed gate insulation layer was 1 μm.

(5) Gate Electrode/Scan Line Formation Step

An Ag nano-colloid solution was coated pattern-wise to the surfaces of the gate insulation layer and the insulation partitioned part by an ink jet method. Thereafter, the substrate was dried at 150° C. for 30 minutes by using a hot plate.

(6) Evaluation

The transistor characteristics of the organic semiconductor transistor of the manufactured organic semiconductor device were measured and as a result, this transistor was found to work as a transistor. At this time, the on-current and off-current of the organic semiconductor transistor were 1×10⁻⁵ A and 5×10⁻¹² A respectively. The voltage resistance of the gate insulation layer and the insulation partitioned part were measured and as a result, it was confirmed that a voltage resistance of 200 V was kept.

### 2. Example 2

In this embodiment, an organic semiconductor device provided with an organic semiconductor transistor having a bottom gate type structure was manufactured.

(1) Gate Electrode/Scan Line Formation Step

A glass substrate which had a size of 150 mm×150 mm×0.7 mm and was formed with Cr 300 nm in thickness on the entire surface thereof by a sputtering method was prepared. The substrate was coated with a photoresist (positive type) by spin coating. The spin coating at this time was carried out at 1800 rpm for 10 seconds. Then, the substrate was dried at 100° C. for one minute and then subjected to pattern-exposure at an intensity of 50 mJ/cm².

Next, the resist of the exposed part was developed and then the substrate was dried at 200° C. for 60 minutes in an oven. Then, Cr at parts in which no resist was present was etched to form a gate electrode and Scan Line.

(2) Insulation Partitioned Part Formation Step

The substrate was coated with an acryl type resin (negative) by spin coating. The spin coating at this time was carried out at 1400 rpm for 20 seconds. Then, the substrate was dried at 100° C. for 2 minutes and then subjected to pattern exposure. Next, the resist of the unexposed part was developed and then the substrate was dried at 200° C. for 60 minutes in an oven to form an insulation partitioned part. At this time, the height of the formed insulation partitioned part was 1.5 μm.

The insulation partitioned part was patterned such that only the part where the gate electrode was formed was opened.

(3) Gate Insulation Layer Formation Step

A coating solution obtained by dissolving PVP (polyvinyl phenol) in a solid concentration of 10 wt % in a n-hexyl alcohol solvent was coated pattern-wise to the inside of the insulation partitioned part by an ink jet method. After that, the substrate was dried at 100° C. for 5 minutes and then at 200° C. for 30 minutes on a hot plate, to form a gate insulation layer. The film thickness of the formed gate insulation layer was 1 μm.

(4) Source/Drain Electrode/Data Line Formation Step

An Ag nano-paste was formed into the form of source/drain electrodes and Data Line by patterning using a screen printing method. Thereafter, the substrate was dried at 200° C. for 30 minutes in an oven, to form a source and drain electrodes.

(5) Formation of an Organic Semiconductor Layer

A coating solution obtained by dissolving an organic semiconductor material (polythiophene) in a solid concentration of 0.2 wt % in a trichlorobenzene solvent was coated pattern-wise to the inside of the insulation partitioned part by an ink jet method. Thereafter, the coating layer was dried at 200° C. for 10 minutes in a N₂ atmosphere by using a hot plate to form an organic semiconductor layer. The thickness of the formed organic semiconductor layer was 0.1 μm.

(6) Evaluation

The transistor characteristics of the organic semiconductor transistor of the manufactured organic semiconductor device were measured and as a result, this transistor was found to work as a transistor. At this time, the on-current and off-current of the organic semiconductor transistor were 8×10⁻⁶ A and 2×10⁻¹² A respectively. The voltage resistance of the gate insulation layer and the insulation partitioned part were measured and as a result, it was confirmed that a voltage resistance of 200 V was kept.

### 3. Comparative Example 1

An organic semiconductor device was manufactured in the same method as in Example 1 except that the thickness of the insulation partitioned part was changed to 3 μm.

The transistor characteristics of the organic semiconductor transistor of the manufactured organic semiconductor device were measured and as a result, this transistor was found to work as a transistor. However, the on-current and off-current of the organic semiconductor transistor were 1×10⁻⁷ A and 5×10⁻⁹ A respectively, showing that this organic semiconductor transistor had the characteristics that the transistor was more reduced in on-off ratio than that having a partitioned part film thickness of 1.5 μm.

### 4. Comparative Example 2

(1) Source/Drain Electrode/Data Line Formation Step

A glass substrate which had a size of 150 mm×150 mm×0.7 mm having a film of ITO 300 nm in thickness formed on the entire surface thereof by a sputtering method was prepared. The substrate was coated with a photoresist (positive type) by spin coating. The spin coating at this time was carried out at 1800 rpm for 10 seconds. Then, the substrate was dried at 100° C. for one minute and then subjected to pattern-exposure at an intensity of 50 mJ/cm².

Next, the resist of the exposed part was developed and then the substrate was dried at 200° C. for 60 minutes in an oven. Then, ITO at parts in which no resist was present was etched to form source and drain electrodes and Data Line. When the formed source and drain electrodes were observed by a reflection type optical microscope, the inter-electrode distance (channel length) between the source and drain electrodes was 50 μm.

(2) Insulation Partitioned Part Formation Step

Next, the substrate was coated with an acryl type resin (negative) by spin coating. The spin coating at this time was carried out at 3000 rpm for 20 seconds. Then, the substrate was dried at 100° C. for 2 minutes and then subjected to pattern exposure at an intensity of 50 mJ/cm². Next, the resist of the unexposed part was developed and then the substrate was dried at 200° C. for 60 minutes in an oven to form an insulation partitioned part. At this time, the height of the formed insulation partitioned part was 0.05 μm.

The patterning of the insulation partitioned part was carried out so as to open only the channel formation region.

(3) Organic Semiconductor Layer Formation Step

A coating solution obtained by dissolving an organic semiconductor material (polythiophene) in a solid concentration of 0.2 wt % in a trichlorobenzene solvent was coated pattern-wise to the inside of the insulation partitioned part by an ink jet method. However, the organic semiconductor solution was flown out of the opening part of the insulation partitioned part and therefore, no transistor could be manufactured.

### 5. Comparative Example 3

An organic semiconductor device was manufactured in the same method as in Example 2 except that the thickness of the insulation partitioned part was changed to 3 μm.

The transistor characteristics of the organic semiconductor transistor of the manufactured organic semiconductor device were measured and as a result, this transistor was found to work as a transistor. At this time, the on-current and off-current of the organic semiconductor transistor were 8×10⁻⁷ A and 2×10⁻¹⁰ A respectively, showing that this organic semiconductor transistor had the characteristics that the transistor was more reduced in on-off ratio than that having a partitioned part film thickness of 1.5 μm.

### 6. Example 4

(1) Gate Electrode/Scan Line Formation Step

A glass substrate which had a size of 150 mm×150 mm×0.7 mm and was formed with Cr 300 nm in thickness on the entire surface thereof by a sputtering method was prepared. The substrate was coated with a photoresist (positive type) by spin coating. The spin coating at this time was carried out at 1800 rpm for 10 seconds. Then, the substrate was dried at 100° C. for one minute and then subjected to pattern-exposure at an intensity of 50 mJ/cm².

Next, the resist of the exposed part was developed and then the substrate was dried at 200° C. for 60 minutes in an oven. Then, Cr at parts in which no resist was present was etched to form a gate electrode and Scan Line.

(2) Insulation Partitioned Part Formation Step

The substrate was coated with an acryl type resin (negative) by spin coating. The spin coating at this time was carried out at 500 rpm for 20 seconds. Then, the substrate was dried at 100° C. for 2 minutes and then subjected to pattern exposure at an intensity of 50 mJ/cm². Next, the resist of the unexposed part was developed and then the substrate was dried at 200° C. for 60 minutes in an oven to form an insulation partitioned part. At this time, the height of the formed insulation partitioned part was 0.05 μm.

The insulation partitioned part was patterned such that only the part where the gate electrode was formed was opened.

(3) Gate Insulation Layer Formation Step

A coating solution obtained by dissolving PVP (polyvinyl phenol) in a solid concentration of 10 wt % in a n-hexyl alcohol solvent was coated pattern-wise to the inside of the insulation partitioned part by an ink jet method. However, the PVP solution was flown out of the opening part of the insulation partitioned part and therefore, no transistor could be manufactured.

What is claimed is:

1. An organic semiconductor device comprising:
a substrate;
a source electrode and a drain electrode which are formed on the substrate;
an insulation partitioned part which is formed on the source electrode and the drain electrode, made of an insulation material, formed such that an opening part of the insulation partitioned part is disposed above a channel region formed by the source electrode and the drain electrode and has a function as an interlayer-insulation layer;
an organic semiconductor layer which is formed in the opening part of the insulation partitioned part and on the source electrode and the drain electrode, and made of an organic semiconductor material;
a gate insulation layer which is formed on the organic semiconductor layer and made of an insulation resin material; and
a gate electrode formed on the gate insulation layer, wherein;
the insulation partitioned part has a height ranging from 0.1 μm to 1.5 μm.

2. An organic semiconductor device comprising:
a substrate;
a gate electrode formed on the substrate;
an insulation partitioned part which is formed on the gate electrode, made of an insulation material, provided with an opening part and has a function as an interlayer-insulation layer;
a gate insulation layer which is formed in the opening part of the insulation partitioned part and on the gate electrode, and made of an insulation resin material;
an organic semiconductor layer which is formed in the opening part of the insulation partitioned part and on the gate insulation layer, and made of an organic semiconductor material; and
a source electrode and a drain electrode which are formed on the organic semiconductor layer, wherein;
the insulation partitioned part has a height ranging from 0.1 μm to 1.5 μm.

3. The organic semiconductor device according to claim 1, wherein the insulation partitioned part has liquid repellency.

4. The organic semiconductor device according to claim 2, wherein the insulation partitioned part has liquid repellency.

5. A manufacturing method of an organic semiconductor device, wherein the method comprises:
a source/drain electrode formation step of using a substrate to form a source electrode and a drain electrode on the substrate;
an insulation partitioned part formation step of forming an insulation partitioned part made of an insulation material on the source electrode and the drain electrode formed in the source/drain electrode formation step such that an opening part of the insulation partitioned part is disposed above a channel region formed by the source electrode and the drain electrode and a height of the insulation partitioned part is in the range from 0.1 μm to 1.5 μm;
an organic semiconductor layer formation step of forming an organic semiconductor layer made of an organic semiconductor material, in the opening part of the insulation partitioned part formed in the insulation partitioned part formation step and on the source electrode and the drain electrode:
a gate insulation layer formation step of forming a gate insulation layer made of an insulation resin material on the organic semiconductor layer formed in the organic semiconductor layer formation step; and
a gate electrode formation step of forming a gate electrode on the gate insulation layer formed in the gate insulation layer formation step.

6. A manufacturing method of an organic semiconductor device, wherein the method comprises:
a gate electrode formation step of using a substrate to form a gate electrode on the substrate;
an insulation partitioned part formation step of forming an insulation partitioned part on the gate electrode formed in the gate electrode formation step such that a height of the insulation partitioned part is in the range from 0.1 μm to 1.5 μm and an opening part of the insulation partitioned part is disposed above the gate electrode;
a gate insulation layer formation step of forming a gate insulation layer made of an insulation resin material, in the opening part of the insulation partitioned part formed in the insulation partitioned part formation step and on the gate electrode;
an organic semiconductor layer formation step of forming an organic semiconductor layer made of an organic semiconductor material on the gate insulation layer formed in the gate insulation layer formation step; and
a source/drain electrode formation step of forming a source electrode and a drain electrode on the organic semiconductor layer formed in the organic semiconductor layer formation step.

7. An organic transistor array using the organic semiconductor device as claimed in claim 1, wherein plural organic semiconductor transistors are formed on the substrate.

8. An organic transistor array using the organic semiconductor device as claimed in claim 2, wherein plural organic semiconductor transistors are formed on the substrate.

9. A display using the organic transistor array as claimed in claim 7.

10. A display using the organic transistor array as claimed in claim 8.
